(19) United States
(12) Patent Application Publication
(10) Pub. No.: US 2026/0235698 A1
(43) Pub. Date: Aug. 13, 2026

(54) METHOD FOR DETECTING OUTLIER BATTERY CELL GROUPS IN REAL-TIME ENERGY STORAGE SYSTEMS

(71) Applicant: TAIWAN TRUEWIN TECHNOLOGY CO., LTD., Hsinchu City (TW)

(72) Inventor: YU-JU CHIU, Hsinchu City (TW)

(21) Appl. No.: 19/052,215

(22) Filed: Feb. 12, 2025

(51) Int. Cl. G01R 31/396; G01R 31/367; G01R 31/3842; G01R 31/392

(52) U.S. Cl. CPC G01R 31/396; G01R 31/367; G01R 31/3842; G01R 31/392

(57) ABSTRACT

This invention discloses a method for diagnosing outliers in operational battery cell groups. The method targets an energy storage system composed of multiple parallel battery cell groups. It involves collecting battery operating data and calculating the skewness and kurtosis of each battery cell group, followed by computing the Z-score. Using a predefined Z-score threshold, the method filters out the outlier battery cell groups. Maintenance personnel can then pay close attention to these outlier groups or replace faulty cells, if necessary, at an earlier stage, before the energy storage system goes beyond control, ensuring the energy storage system continues to function normally.

### BACKGROUND

### Technical Field

This invention relates to an outlier diagnosis method for multiple groups of battery cells in an energy storage system, particularly a method of identifying outlier battery cell groups based on the calculation of skewness and kurtosis.

### Description of Related Art

Conventional techniques focus on the quality inspection of individual battery cells, with no emphasis on the quality consistency inspection among groups for an energy storage system. The inventors of this case have first proposed a method to inspect the quality consistency among groups in a structure where multiple series-connected battery groups are parallel connected. By identifying outlier groups, this method allows for early correction or replacement of defective units, maintaining the normal quality of the system and preventing the overall system from gradually deteriorating over time.

### SUMMARY OF THE INVENTION

An energy storage system has the capability of rapid charging and discharging. When the energy storage system is electrically coupled with the official power grid, it can provide auxiliary services to the grid, executing the Automatic Frequency Control (AFC) function. By outputting or inputting power to correct frequency deviations, it helps maintain the stability of the grid against frequency drifts caused by load fluctuations, thereby enhancing the overall stability of the official power grid.

This invention discloses a method for outlier diagnosis of multiple groups of battery cells in an energy storage system, where the energy storage system includes multiple groups of battery cells operating in parallel. The invention calculates the skewness and kurtosis of each group, then calculates their Z-scores respectively. Based on the set Z-score threshold, it identifies the outlier battery cell groups. If outlier groups are detected, we can promptly correct these groups or replace the faulty battery cells to maintain the basic operational functions of the entire energy storage system.

### BRIEF DESCRIPTION OF THE DRA WINGS

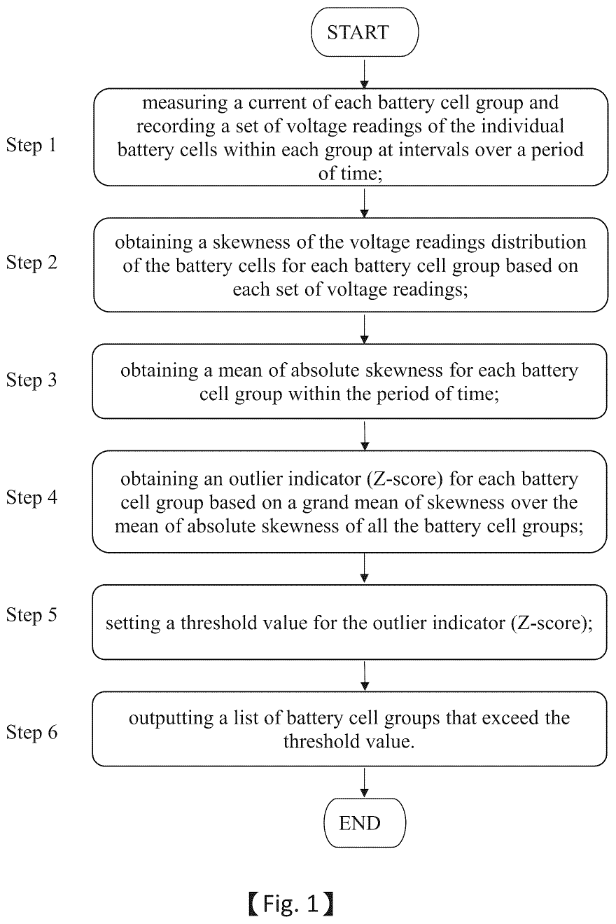

FIG. 1 shows a first embodiment according to the present invention.

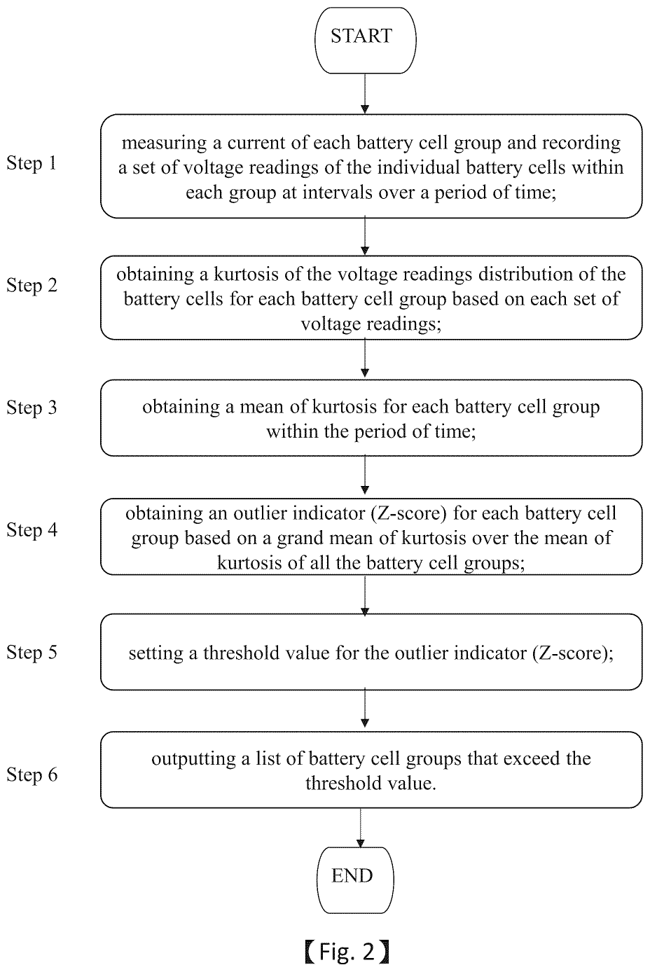

FIG. 2 shows a second embodiment according to the present invention.

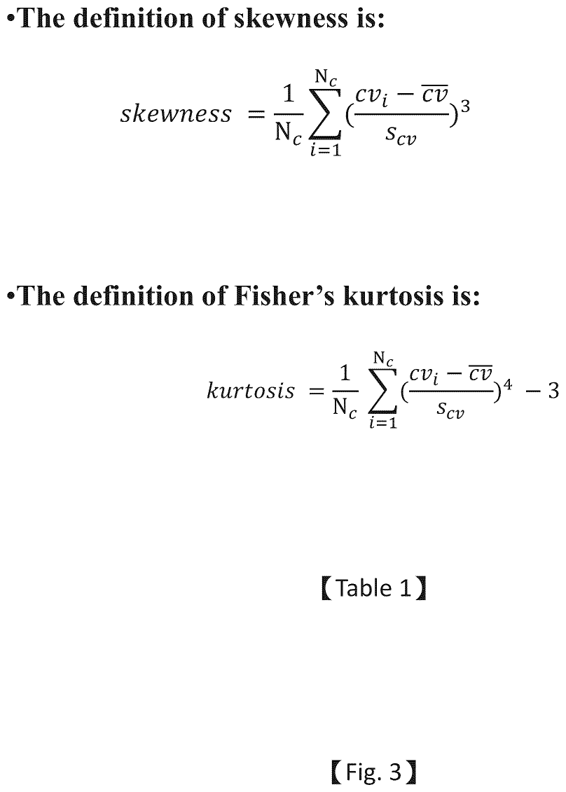

FIG. 3 includes Table 1 that shows the definitions of skewness and kurtosis.

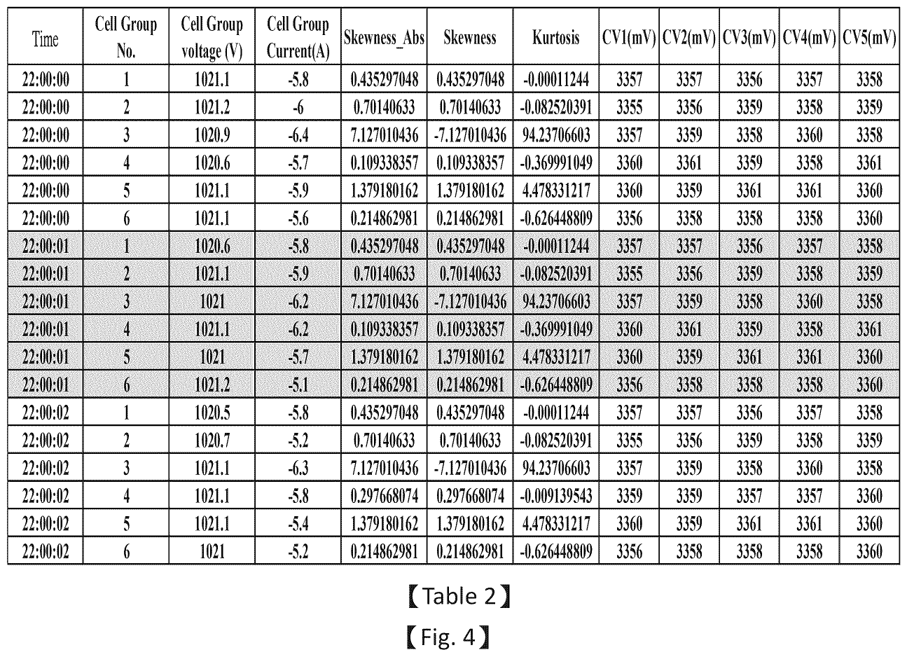

FIG. 4 includes Table 2 that shows a sample of the raw data, with 304 battery cells, displaying the voltages of the first five battery cells for three seconds as an example.

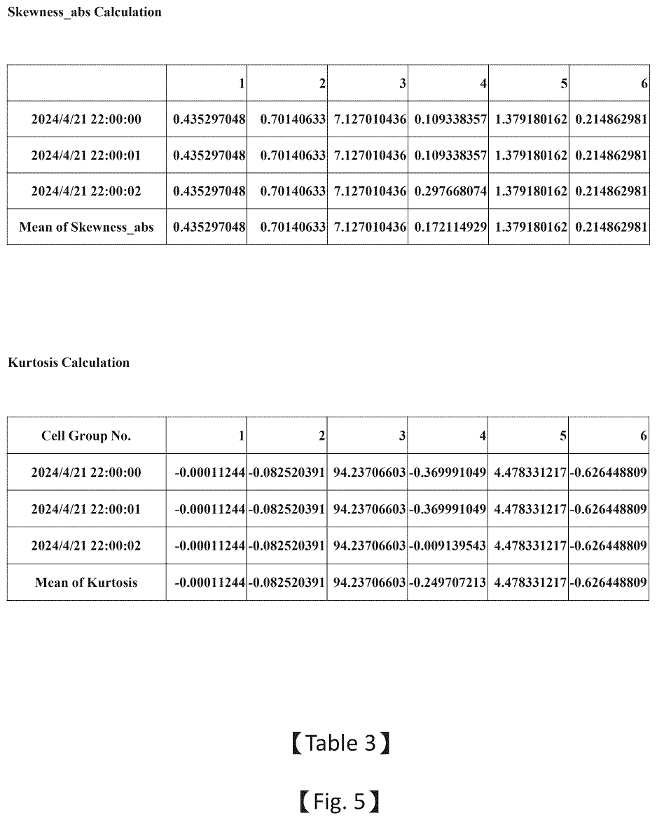

FIG. 5 includes Table 3 that shows the calculation of the absolute value average of skewness and the average of kurtosis.

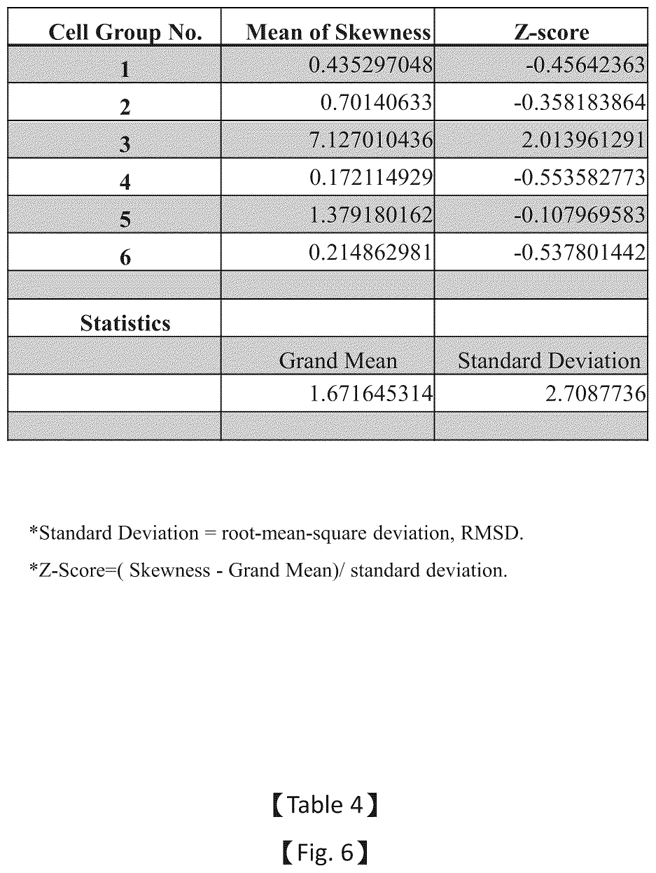

FIG. 6 includes Table 4 that shows the statistics of skewness and Z-score.

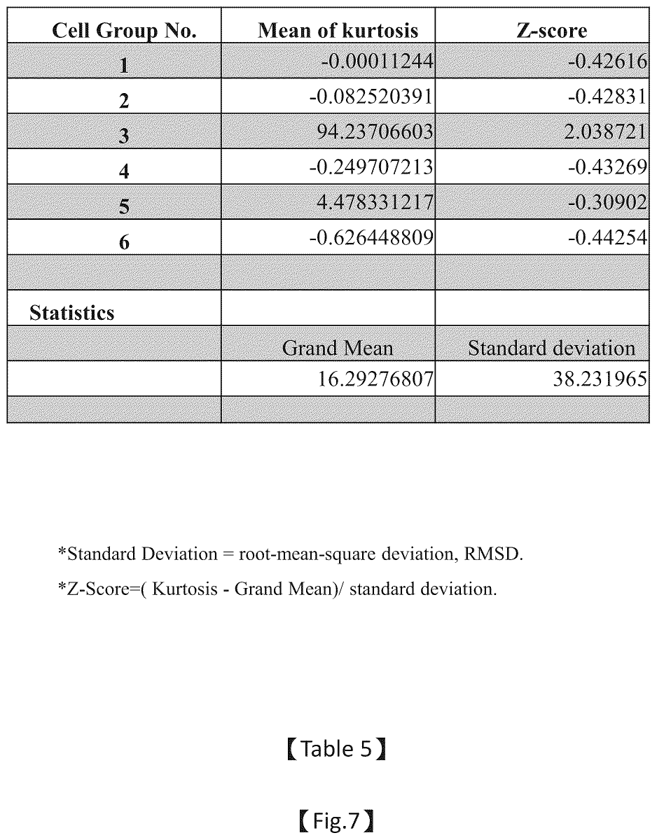

FIG. 7 includes Table 5 that shows the statistics of kurtosis and Z-score.

### DETAILED DESCRIPTION OF THE INVENTION

We use the following example for illustration purposes. The specifications in the example are provided for convenience of explanation and should not be construed as limiting the scope of the invention.

### Example Explanation:

An energy storage system consists of six groups of battery cells, each group containing 304 series-connected battery cells. The six groups of battery cells, along with devices such as the Power Conversion System (PCS), form an energy storage system. This energy storage system can be electrically coupled to the official power grid to provide Automatic Frequency Control (AFC) services, enhancing the stability of the official power grid. In the operation of the energy storage system, this invention uses skewness and kurtosis, along with Z-scores, to check whether there are any outlier battery cell groups among the six groups of battery cells.

Table 1 in FIG. 3 shows the definition of skewness and definition of Fisher's kurtosis.

In this invention, six groups of battery cells are used in parallel, forming an energy storage system. Each battery cell group contains 304 battery cells. The goal of the invention is to identify any outlier battery cell groups among the six groups. The diagnostic method of the invention is as follows: Statistical analysis of the voltages of the 304 battery cells in each group, from the voltage of the 1st battery cell (CV1) to the voltage of the 304th battery cell (CV304). Calculate the skewness and kurtosis values of each battery cell group. The operational steps are as follows:
1. Calculate the skewness and kurtosis for each battery cell group respectively.
2. Select data in the range of current sizes from 4 A to 10 A and from −4 A to −10 A for analysis. The performance of the battery varies under different currents; when the current is too small, it approaches the open circuit voltage, and the voltage distribution difference is not significant. Larger currents also reduce the voltage distribution difference. Therefore, time-domain analysis is converted to current-domain analysis.

The present invention uses battery cell groups with a rated capacity of 200 Ah. When the discharge current is 4 A, its discharge rate is 0.02 C (4 A/200 A=0.02 C); when the discharge current is 10 A, its discharge rate is 0.05 C (10 A/200 A=0.05 C). The selected current range for this invention is based on a C-rate of 0.02 C to 0.05 C. Other selectable wider current ranges include a C-rate of 0.02 C to 0.20 C.
3. Since the sign of the skewness represents the direction of deviation, the absolute value of skewness is used to calculate the magnitude of deviation.
4. Calculate the mathematical mean of the absolute value of skewness and the mean of kurtosis for each battery cell group respectively.
5. Use the mean to calculate the outlier indicator Z-score for the skewness and kurtosis of each battery cell group.
6. Set the outlier indicator threshold value Z-score >2 to identify the third battery cell group as an outlier battery cell group.

### Calculation of the Mean and Standard Deviation of the Battery Cell Voltages:

$$\overline{cv} = \frac{{\sum }_{i = 1}^{{N}_{c}} c {v}_{i}}{{N}_{c}} , {S}_{c v} = \sqrt{\frac{{\sum }_{i = 1}^{{N}_{c}} {( {cv}_{i} - \overline{cv} )}^{2}}{{N}_{c}}}$$

wherein,
Nc represents the number of battery cells in each battery cell group;
CVi is the voltage of the i-th battery cell;
c̅v̅ is the average voltage of Nc battery cells; and
Scv is the standard deviation of the voltages of Nc battery cells.

The raw data sample is shown in Table 2 in FIG. 4. Table 2 summarizes the data for three seconds only and the voltages of the first five battery cells only as an example, including: time, cell group number, cell group voltage, cell group current, absolute value of skewness (skewness_Abs), skewness, kurtosis, and the voltages of the first five battery cells (CV1, CV2, CV3, CV4, CV5).

Table 2 shows a raw data sample, featuring 304 battery cells, using the voltage data of the first five battery cells and the data collected over three seconds only as an example:

The first group of 304 battery cells, each measured for their voltage (CV1~CV304), had an absolute skewness value of 0.435297048 and a kurtosis of −0.00011244 at 22:00:00.

The second group of 304 battery cells, each measured for their voltage (CV1~CV304), had an absolute skewness value of 0.70140633 and a kurtosis of −0.082520391 at 22:00:00.

The third group of 304 battery cells, each measured for their voltage (CV1~CV304), had an absolute skewness value of 7.127010436 and a kurtosis of 94.23706603 at 22:00:00.

The fourth group of 304 battery cells, each measured for their voltage (CV1~CV304), had an absolute skewness value of 0.109338357 and a kurtosis of −0.369991049 at 22:00:00.

The fifth group of 304 battery cells, each measured for their voltage (CV1~CV304), had an absolute skewness value of 1.379180162 and a kurtosis of 4.478331217 at 22:00:00.

The sixth group of 304 battery cells, each measured for their voltage (CV1~CV304), had an absolute skewness value of 0.214862981 and a kurtosis of −0.626448809 at 22:00:00.

The significance of the information at 22:00:01 and 22:00:02 is similar to the above and is not further elaborated.

### Table 3 in FIG. 5 Shows the Calculation of an Average of the Absolute Skewness and the Average of Kurtosis.

Table 3 is based on the data in Table 2, showing the calculation of the average of absolute skewness and the average of kurtosis. Table 3 uses the first three seconds of data from Table 2 as an example for illustration. Taking the mean of the data from the first three seconds, the averages of absolute skewness for the battery cell groups 1 to 6 are calculated as: 0.435297048; 0.70140633; 7.127010436; 0.172114929; 1.379180162; and 0.214862981 respectively.

Taking the mean of the data from the first three seconds, the kurtosis averages for the battery cell groups 1 to 6 are calculated as: −0.00011244; −0.082520391; 94.23706603; −0.249707213; 4.478331217; and −0.626448809 respectively.

### Table 4 in FIG. 6 Shows the Statistics of Skewness and Z-Score.

$$z - {score}_{i} = \frac{{x}_{i} - \overline{x}}{Sx} , \\ \overline{x} = \frac{{\sum }_{i = 1}^{{N}_{G}} {x}_{i}}{{N}_{G}} , \\ {S}_{x} = \sqrt{\frac{{\sum }_{i = 1}^{{N}_{G}} {( {x}_{i} - \overline{x} )}^{2}}{{N}_{G}}}$$

wherein, x̅ is mean of xᵢ; sₓ is a standard deviation ∘

For skewness, among the N_{G} battery cell groups, if xᵢ is the average skewness value of the i-th battery cell group, the skewness Z-score of the i-th battery cell group can be calculated as shown in Table 4.

For kurtosis, among the N_{G} battery cell groups, if xᵢ is the average kurtosis value of the i-th battery cell group, the kurtosis Z-score of the i-th battery cell group can be calculated as shown in Table 5.

Table 4 shows the skewness values for the six groups of battery cells as: 0.435297048, 0.70140633, 7.127010436, 0.172114929, 1.379180162, and 0.214862981 respectively.

The mean of the skewness values for the six groups of battery cells is 1.671645314, and the standard deviation is 2.7087736.

The Z-score is calculated as:

$$Z - score = ( skewness - grand mean ) / standard deviation .$$

The Z-scores for the first to the sixth groups are: −0.45642363, −0.358183864, 2.013961291, −0.553582773, −0.107969583, and −0.537801442 respectively.

If the Z-score threshold is set to 2, any Z-score greater than 2 is considered as identifying an outlier battery cell group. The third battery cell group has a Z-score of 2.013961291. With a Z-score threshold of 2, the third battery cell group would be identified as an outlier battery cell group.

### Table 5 in FIG. 7 Shows the Statistics of Kurtosis and Z-Score.

In this invention, the kurtosis values of battery cell groups are calculated using Fisher's kurtosis as an example, with the statistical method similar to the previous example. In this invention, the outlier indicator for the kurtosis values of battery cell groups is calculated using the average kurtosis values of each battery cell group to compute the Z-scores. In this invention, a Z-score threshold of 2 is used as an example.

Table 5 shows the kurtosis values for the six groups of battery cells respectively as: −0.00011244, −0.082520391, 94.23706603, −0.249707213, 4.478331217, and −0.626448809.

The mean of the kurtosis values for the six groups of battery cells is 16.29276807, and the standard deviation is 38.231965.

The Z-score is calculated as:

$$Z - score = ( kurtosis - grand mean ) / standard deviation .$$

The Z-scores for the first to the sixth groups are: −0.42616, −0.42831, 2.038721, −0.43269, −0.30902, and −0.44254 respectively.

If the Z-score threshold is set to 2, any Z-score greater than 2 is considered an outlier battery cell group. The third battery cell group has a Z-score of 2.013961291. With a Z-score threshold of 2, the third battery cell group would be identified as an outlier battery cell group.

In the above example, we took three seconds of data for analysis. In actual operation, data analysis can be done in minutes, hours, or even days, etc.

### FIG. 1 Shows a First Embodiment According to the Present Invention.

FIG. 1 shows a method for diagnosing outlier battery cell groups based on skewness during operation. The steps include:
Step 1 comprises measuring a current of each battery cell group and recording a set of voltage readings of the individual battery cells within each group at intervals over a period of time; as shown in Table 2;
Step 2 comprises obtaining a skewness of the voltage readings distribution of the battery cells for each battery cell group based on each set of voltage readings;
Step 3 comprises obtaining a mean of absolute skewness for each battery cell group within the period of time; as shown in Table 3;
Step 4 comprises obtaining an outlier indicator (Z-score) for each battery cell group based on a grand mean of skewness over the mean of absolute skewness of all the battery cell groups; as shown in Table 4;
Step 5 comprises setting a threshold value for the outlier indicator (Z-score); and
Step 6 comprises outputting a list of battery cell groups that exceed the threshold value.

### FIG. 2 Shows a Second Embodiment According to the Present Invention.

FIG. 2 shows a method for diagnosing outlier battery cell groups based on kurtosis during operation. The steps include:
Step 1 comprises measuring a current of each battery cell group and recording a set of voltage readings of the individual battery cells within each group at intervals over a period of time; as shown in Table 2;
Step 2 comprises obtaining a kurtosis of the voltage readings distribution of the battery cells for each battery cell group based on each set of voltage readings; as shown in Table 3;
Step 3 comprises obtaining a mean of kurtosis for each battery cell group within the period of time; as shown in Table 5;
Step 4 comprises obtaining an outlier indicator (Z-score) for each battery cell group based on a grand mean of kurtosis over the mean of kurtosis of all the battery cell groups;
Step 5 comprises setting a threshold value for the outlier indicator (Z-score); and
Step 6 comprises outputting a list of battery cell groups that exceed the threshold value.

While this specification has detailed several embodiments through examples, those skilled in the art may make various evident modifications without straying from the essence of the appended claims. These modifications are still encompassed within the scope of the present invention.

What is claimed is:

1: A method for detecting outlier battery cell groups in real-time energy storage systems based on skewness, wherein the energy storage system comprises multiple groups of battery cells, connected in parallel, with each group containing a plurality of series-connected battery cells, the method comprising:
Step 1 comprises measuring a current of each battery cell group and recording a set of voltage readings of the individual battery cells within each group at intervals over a period of time;
Step 2 comprises obtaining a skewness of the voltage readings distribution of the battery cells for each battery cell group based on each set of voltage readings;
Step 3 comprises obtaining a mean of absolute skewness for each battery cell group within the period of time;
Step 4 comprises obtaining an outlier indicator (Z-score) for each battery cell group based on a grand mean of skewness over the mean of absolute skewness of all the battery cell groups;
Step 5 comprises setting a threshold value for the outlier indicator (Z-score); and
Step 6 comprises outputting a list of battery cell groups that exceed the threshold value.

2: The method as described in claim 1, wherein
the intervals in step 1 refer to seconds, minutes, hours, days, weeks, or months.

3: The method as described in claim 1, wherein
the obtaining a skewness in Step 2 uses data within a selected range of currents for the battery cell group.

4: The method as described in claim 3, wherein
the selected range of currents is based on C-rates between 0.02 C and 0.20 C.

5: The method as described in claim 4, wherein
the selected range of currents is based on C-rates between 0.02 C and 0.05 C.

6: A method for detecting outlier battery cell groups in real-time energy storage systems based on kurtosis, wherein the energy storage system comprises multiple groups of battery cells, connected in parallel, with each group containing a plurality of series-connected battery cells, the method comprising:
Step 1 comprises measuring a current of each battery cell group and recording a set of voltage readings of the individual battery cells within each group at intervals over a period of time;
Step 2 comprises obtaining a kurtosis of the voltage readings distribution of the battery cells for each battery cell group based on each set of voltage readings;
Step 3 comprises obtaining a mean of kurtosis for each battery cell group within the period of time;
Step 4 comprises obtaining an outlier indicator (Z-score) for each battery cell group based on a grand mean of kurtosis over the mean of kurtosis of all the battery cell groups;
Step 5 comprises setting a threshold value for the outlier indicator (Z-score); and
Step 6 comprises outputting a list of battery cell groups that exceed the threshold value.

7: The method as described in claim 6, wherein
the intervals in step 1 refer to seconds, minutes, hours, days, weeks, or months.

8: The method as described in claim 6, wherein
the obtaining a kurtosis in Step 2 uses data within a selected range of currents for the battery cell group.

9: The method as described in claim 8, wherein
the selected range of currents is based on C-rates between 0.02 C and 0.20 C.

10: The method as described in claim 9, wherein
the selected range of currents is based on C-rates between 0.02 C and 0.05 C.
